(19) United States
(12) Patent Application Publication
(10) Pub. No.: US 2012/0073648 A1
(43) Pub. Date: Mar. 29, 2012

(54) Photovoltaic conversion using rare earths plus Group IV Sensitizers

(76) Inventors: Andrew Clark, Palo Alto, CA (US); Robin Smith, Palo Alto, CA (US); Scott Semans, Palo Alto, CA (US); F. Erdem Arkun, Palo Alto, CA (US); Michael Lebby, Palo Alto, CA (US)

(21) Appl. No.: 12/890,537

(22) Filed: Sep. 24, 2010

(51) Int. Cl. H01L 31/0232

(52) U.S. Cl. 136/257

(57) ABSTRACT

The invention relates to photovoltaic device structures of more than one layer comprising rare earth compounds and Group IV materials enabling spectral harvesting outside the conventional absorption limits for silicon.

### CROSS REFERENCE TO RELATED APPLICATIONS

Applications and patents 09/924,392, 10/666,897, 10/746,957, 10/799,549, 10/825,912, 10/825,974, 11/022,078, 11/025,363, 11/025,680, 11/025,681, 11/025,692, 11/025,693, 11/084,486, 11/121,737, 11/187,213, U.S. 20050166834, U.S. 20050161773, U.S. 20050163692, 11/053,775, 11/053,785, 11/054,573, 11/054,579, 11/054,627, 11/068,222, 11/188,081, 11/253,525, 11/254,031, 11/257,517, 11/257,597, 11/393,629, 11/398,910, 11/472,087, 11/788,153, 11/858,838, 11/960,418, 12/119,387, 60/820,438, 60/811,311, 61/089,786, 12/171,200, 12/119,387, 12/408,297, 12/510,977, 12/619,621, 12/619,549, 12/619,637, 60/847,767, 60/944,369, 60/949,753, 61/312,061, 61/301,597, 61/298,896, U.S. Pat. No. 7,018,484, U.S. Pat. No. 7,037,806, U.S. Pat. No. 7,135,699, U.S. Pat. No. 7,199,015, U.S. Pat. No. 7,586,177, and U.S. Pat. No. 7,807,917, all held by the same assignee, contain information relevant to the instant invention and are incorporated herein in their entirety by reference. U.S. Pat. No. 7,589,003, U.S. Pat. No. 7,598,513, U.S. application Ser. No. 12/133,225 and PCT/US2009/057213, published as WO2010/044978 contain information relevant to the instant invention, are licensed by the assignee and are incorporated herein in their entirety by reference. References noted in the specification and Information Disclosure Statement are incorporated herein in their entirety by reference.

### BACKGROUND OF THE INVENTION

1. Field of the Invention

The invention relates generally to photovoltaic device structures of more than one layer comprising rare earth compounds and Group IV materials enabling spectral harvesting outside the conventional absorption limits for silicon.

2. Description of Related Art Including Information Disclosed Under 37 CFR 1.97 and 1.98.

As an alternative approach to multiple junction solar cells where specific materials are matched to discrete portions of the solar spectrum, spectral harvesting works on the principle of moving parts of the spectrum to the wavelength band of a single junction cell. For example it is widely accepted that a single junction, single crystal silicon solar cell has an optimum performance in the wavelength range 500 to 1,100 nm, whilst the solar spectrum extends from 400 nm to in excess of 2,500 nm.

Rare earths, the lanthanide series, have long been known for the unique optical properties in which the incomplete, 4f shells exhibit multiple optical transitions many of which lie within the solar spectrum. Examples of some of these optical transitions are: Er: 410 nm, 519 nm, 650 nm, 810 nm, 972 nm, 1,529 nm; Yb: 980 nm; Tb: 485 nm.

Certain rare earths and combinations of rare earths, optionally, with one or more transition metals and/or one or more Group IV elements, can absorb light at one wavelength (energy) and re-emit at another wavelength (energy). This is the essence of spectral harvesting; when the incident, adsorbed, radiation energy per photon is less than the emission, emitted, energy per photon the process is referred to as “up-conversion”. “Down-conversion” is the process in which the incident energy per photon is higher than the emission energy per photon. An example of up conversion is Er absorbing at 1,480 nm and exhibiting photoluminescence at 972 nm.

Sensitization of RE materials with transition metals Cr and V is taught in the prior art; in particular the use of Cr⁵⁺ within an Er doped YVO₄ powder for up-conversion of infrared light to visible light. In this invention we disclose films deposited on semiconductor devices, optionally photovoltaic devices. A. C. Pan, et al. in “Characterization of up-converter layers on bifacial silicon solar cells”; Matls. Sci. & Engin., 159-160 (2009), 212; describe rare earth-doped zinc/cadmium sulphides or selenides phosphor films applied to a solar cell as a spin-on oxide or with silicone gel. A. C. Pan has also published on rare earths in combination with PbS quantum dots as up-converters. A. Polman, et al., disclose up conversion a film of Si nanocrystals in a SiO₂ matrix doped with Er³⁺ ions in “Broadband sensitizers for erbium-doped planar optical amplifiers”; J. Opt. Soc. Am. B, 21, No. 5, May 2004. Other references cited in the Information Disclosure Statement include, Gong, 20010; Chang, 2006; Choi, 2007; Isshiki, 2005, 2006, 2008, etc.; Zhao, 2007; Kimura, 2006; Liu, 2007; Qi, 2000; Sands, 1990; Schaevitz, 2008; Sh, 2006; Goldschmidt, 2009; AC Pan, 2009; Michael, 2008; Polman, 2004; Presting, 2002; all incorporated herein in their entirety by reference.

Silicon quantum dots have been demonstrated in Gd₂O₃ layers grown on silicon wafers for use as optical absorber materials, where the Gd₂O₃ acts as an inert matrix for the Si nano dots. In the discussion, it is implied that electrons would be extracted directly from the Si nano dots, and that the REO layer does not have an electrical or optical function in the device. The present invention discloses Group IV nano dots in a fundamentally different way in that energy is absorbed by a Group IV nano dot and then transferred via resonant energy transfer into an optically active REO matrix containing at least one optically active RE ion diluted in an inert REO matrix. The present invention also discloses the use of carbon as a nano dot and mixtures of Group IV elements as an optical absorber material.

U.S. Pat. No. 6,613,974 discloses a tandem Si—Ge solar cell with improved efficiency; the disclosed structure is a silicon substrate onto which a Si—Ge epitaxial layer is deposited and then a silicon cap layer is grown over the Si—Ge layer; no mention of rare earths is made. U.S. Pat. No. 7,364,989 discloses a silicon substrate, forming a silicon alloy layer of either Si—Ge or Si—C and the depositing a single crystal rare earth oxide, binary or ternary; the alloy content of the alloy layer is adjusted to select a type of strain desired; the preferred type of strain is “relaxed”; the preferred deposition method for the rare earth oxide is atomic layer deposition at temperatures below 300° C. While the Si—Ge film is “relaxed”, its primary function is to impart no strain, tensile strain or compressive strain to the rare earth oxide layer; the goal being to improve colossal magnetoresistive, CMR, properties of the rare earth oxide. A preferred method disclosed requires a manganese film be deposited on a silicon alloy first. Recent work on rare earth films deposited by an ALD process indicate the films are typically polycrystalline or amorphous.

U.S. Pat. No. 7,432,550 discloses a method of forming a semiconductor structure including a rare earth oxide on silicon; use of LaₓY₁₋ₓ)₂O₃ as an intermediate layer on freshly grown silicon or SiO₂ is disclosed; strain engineering is not employed. U.S. Pat. No. 72,48,226, by the same inventors, discloses depositing amorphous silicon on a rare earth oxide and the recrystallizing it at an elevated temperature. U.S. Pat. No. 6,670,544 discloses a Si—Ge thin film solar cell having a quantum well structure; rare earth oxides are not disclosed. U.S. Pat. No. 7,599,593 discloses Si—Ge quantum wells comprising two buffer layers; rare earths are not disclosed.

U.S. Pat. No. 7,589,003, U.S. Pat. No. 7,598,513, WO2010/044978 and U.S. application Ser. No. 12/133,225 disclose methods and structures for depositing Ge₁₋ₓSnₓ layer on a silicon substrate wherein the Ge₁₋ₓSnₓ layer has a direct band gap between about 0.72 and about 0.041 eV. Also disclosed are SiₓGe₁₋ₓSn_{y}Ge_{1-x-y} layers grown on Si substrates wherein x≦0.25 and y≦0.11 and the band gap is between about 0.80 and about 1.40 eV; in some embodiments a high-k dielectric layer, optionally comprising a Lanthanum based oxide, is part of a semiconductor structure consisting of a second Si-based layer comprising elemental silicon.

Liu, J., et al. in “Tensile-strained, n-type Ge as a gain medium for monolithic laser integration on Si”; Optics Express, 3 Sep. 2007/Vol. 15, No. 18, 11272, analyze the optical gain of tensile-strained n-type Ge material for Si-compatible laser applications. Michael, et al., in “Growth, processing and optical properties of epitaxial Er₂O₃ on silicon”; Optics Express, 24 Nov. 2008/Vol. 16, No. 24, 19649 discloses erbium-doped materials for generating and amplifying light in low-power chip-scale optical networks on silicon. Laha, et al. in “Encapsulated solid phase epitaxy of a Ge quantum well embedded in an epitaxial rare earth oxide”; 2009 Nanotechnology 20, 475604 disclose a method to integrate an epitaxial Ge quantum well into a single crystalline rare earth oxide comprising Gd₂O₃—Ge—Gd₂O₃ grown on a silicon substrate. The prior art does not disclose a semiconductor structure incorporating rare earth and Si—Ge—Sn based layers for spectral harvesting in a photovoltaic device configuration.

### BRIEF SUMMARY OF THE INVENTION

In some embodiments the instant invention discloses materials as thin films operable with a solar cell or photovoltaic device(s). One advantage of thin films is the control provided over a process both in tuning a material to a particular wavelength and in reproducing the process in a manufacturing environment. In some embodiments, rare earth oxides, nitrides, and phosphides, transition metals and Group IV materials and various combinations thereof are employed. The instant invention discloses a device structure enabling increased conversion efficiency by harvesting a larger portion of the solar spectrum than conventional technology by coupling a Group IV based broadband absorber to a rare earth based photoluminescent layer.

### BRIEF DESCRIPTION OF THE DRAWINGS

FIGS. 1a, b, c are schematic illustrations of embodiments of the invention.

FIGS. 2a and b are schematic illustrations of different embodiments.

FIGS. 3a, b and c are schematic illustrations of a REO emitter and Group IV absorber.

FIG. 4a is a schematic illustration of an embodiment; FIG. 4b shows RE absorption vs. Ge mole fraction and band gap.

FIGS. 5a and b are schematic illustrations of one embodiment and an optional repeating structure.

FIG. 6 is schematic illustration of an embodiment with multiple repeating layers, optionally of different compositions.

FIG. 7 is a schematic illustration of an embodiment with multiple layers and predetermined thickness and strain in each layer.

FIG. 8a is a schematic illustration of an embodiment with a discrete quantum dot inclusions; FIG. 8b is a schematic illustration of an embodiment with discrete quantum dot inclusions in a single layer.

FIG. 9 shows photoluminescence data from a REO layer comprising Group IV sensitizers.

FIG. 10 is an exemplary REO layer with Ge sensitizer.

FIG. 11 shows absorption and emission location for various REOn compositions.

### DEFINITIONS

As used herein a rare earth, [REa, REb, . . . RE_{q}], is chosen from the lanthanide series of rare earths from the periodic table of elements {⁵⁷La, ⁵⁸Ce, ⁵⁹Pr, ⁶⁰Nd, ⁶¹Pm, ⁶²Sm, ⁶³Eu, ⁶⁴Gd, ⁶⁵Tb, ⁶⁶Dy, ⁶⁷Ho, ⁶⁸Er, ⁶⁹Tm, ⁷⁰Yb and ⁷¹Lu} plus yttrium, ³⁹Y, and scandium, ²¹Sc, are included as well for the invention disclosed. As used herein a “REO” layer contains two or more elements, at least one chosen from a rare earth and at least one chosen from oxygen and/or nitrogen and/or phosphorous and/or mixtures thereof; structures are not limited to specific rare-earth elements cited in examples. REO[N], or [REO]n, is used to mean a compound of the form (REₐ, RE_{b}, . . . RE_{q})_{w}OₓN_{y}P_{z}, wherein there is at least one rare earth, at least one of a, b, . . . q is greater than zero, and w>0 and at least one of x, y, z is >0. In some embodiments, in addition to REO an alloy may include one or more Group IV elements such as Si and/or Ge and/or C and/or Sn and mixtures thereof. As used herein, S1, S2, S3, . . . Sm are mixtures of Group IV elements wherein S1 is CᵥSiₓGe_{y}Sn_{z} and S2 is CₐSi_{b}Ge_{c}Sn_{d} and so on and at least one of (a, b, c, d) and one of (v, x, y, z) are greater than zero. In this context, S1:REO[1], alternatively REO₁, refers to a specific Group IV based composition in combination with a specific REO composition; in general S1 is different than S2 and REO[1] different than REO[2]; however there may be embodiments when 1, 2, 3, etc. are the same. In some embodiments a layer of a disclosed structure may consist of only Group IV elements, as in S1, CᵥSiₓGe_{y}Sn_{z}.

As used herein a transition metal, [TM1, TM2 . . . TMₙ], is chosen from the transition metal elements consisting of {²²Ti, ²³V, ²⁴Cr, ²⁵Mn, ²⁶Fe, ²⁷Co, ²⁸Ni, ²⁹Cu, ³⁰Zn, ⁴⁰Zr, ⁴¹Nb, ⁴²Mo, ⁴³Tc, ⁴⁴Ru, ⁴⁵Rh, ⁴⁶Pd, ⁴⁷Ag, ⁴⁸Cd, ⁷¹Lu, ⁷²Hf, ⁷³Ta, ⁷⁴W, ⁷⁵Re, ⁷⁶Os, ⁷⁷Ir, ⁷⁸Pt, ⁷⁷Au, ⁸⁰Hg}. Group IV materials include Carbon, Silicon, Germanium, Tin and Lead and mixtures thereof; Groups III, V and Groups II, VI elements have the conventional meaning and include II-V mixtures and II-VI mixtures. As used herein all materials and/or layers may be present in a single crystalline, polycrystalline, nanocrystalline, nc, nanodot or quantum dot and amorphous form and/or mixture thereof; in some cases a Group IV layer may be hydrogenated, for example, as in Si:H or nanocrystalline hydrogenated, nc-Si:H.

It should be understood that when a layer is referred to as being “on” or “over” another layer or substrate, it can be directly on the layer or substrate, or an intervening layer may also be present. It should also be understood that when a layer is referred to as being “on” or “over” another layer or substrate, it may cover the entire layer or substrate or a portion of the layer or substrate.

It should be further understood that when a layer is referred to as being “directly on” or “directly over” another layer or substrate, the two layers are in direct contact with one another with no intervening layer. It should also be understood that when a layer is referred to as being “directly on” or “directly over” another layer or substrate, it may cover the entire layer or substrate, or a portion of the layer or substrate.

The terms “region” and “block” as used herein, mean a single-layer or a multi-layer structure. The term “active block” as used herein, means an active single layer or multilayer, such as a heterostructure, p-n junction, p-i-n junction, or single quantum well (QW) or multiple QW, single or multiple quantum dots, that can provide a photocurrent under incident radiation.

### DETAILED DESCRIPTION OF THE INVENTION

Examples of device structures utilizing layers of single crystal rare earth oxides to perform the tasks of up conversion, and/or down conversion along with, optionally, designing in required optical and/or anti reflective properties are now given. In embodiments of the instant invention, v, x, y and z range from 0 up to and including 1. A substrate may be silicon, poly or multi-crystalline silicon, silicon dioxide, glass or alumina; as used herein multi-crystalline includes poly, micro and nano crystalline. The number of REO/Si(1-y)Ge(y) bilayers may range from one to more than one hundred. “A layer” also comprises multiple layers, optionally. REO, Si(1-x)Ge(x), Si(1-y)Ge(y), and Si(1-z)Ge(z) layers are, optionally, single crystal, multi-crystalline or amorphous layers and are, optionally, optically active dielectrics compatible with semiconductor processing techniques. In some embodiments a low cost substrate such as soda glass or polycrystalline alumina is used in combination with a rare-earth based structure comprising a diffusion barrier layer, a buffer layer, an active region, up and/or down layer(s), one or more reflectors, one or more Bragg layers, texturing is optional; one or more layers may comprise a rare-earth. The exact sequence of the layers is application dependent; in some cases sunlight may enter a transparent substrate initially; in other cases a transparent substrate may be interior of multiple layers.

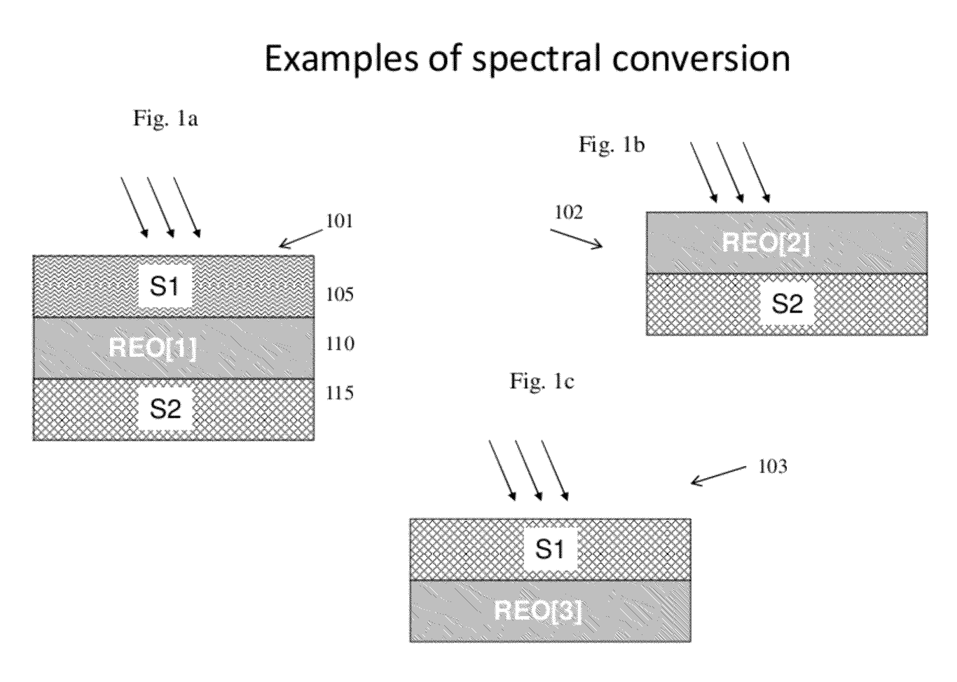

FIGS. 1a-c illustrate several embodiments; structure 101 has rare earth layer 110 between semiconductor layers S1, 105, and S2, 115 with radiation impinging on S1 initially; structure 102 in FIG. 1b has REO[2] layer between incoming radiation and layer S2; similarly structure 103 in FIG. 1c has S1 layer between incoming radiation and REO[3] layer; in all cases the REO layer is re-emitting radiation at one or more preselected wavelengths based upon its composition and construct of one or more layers; in all cases the Group IV, Sm, layers are functioning as broadband absorbers and the REO layer has spectral up-converting and/or down-converting capabilities. In some embodiments semiconductor structures comprising Ge_{1-x-y}SiₓSn_{y} alloys are disclosed that have tunable band gaps ranging between about 0.80 eV to about 1.40 eV.

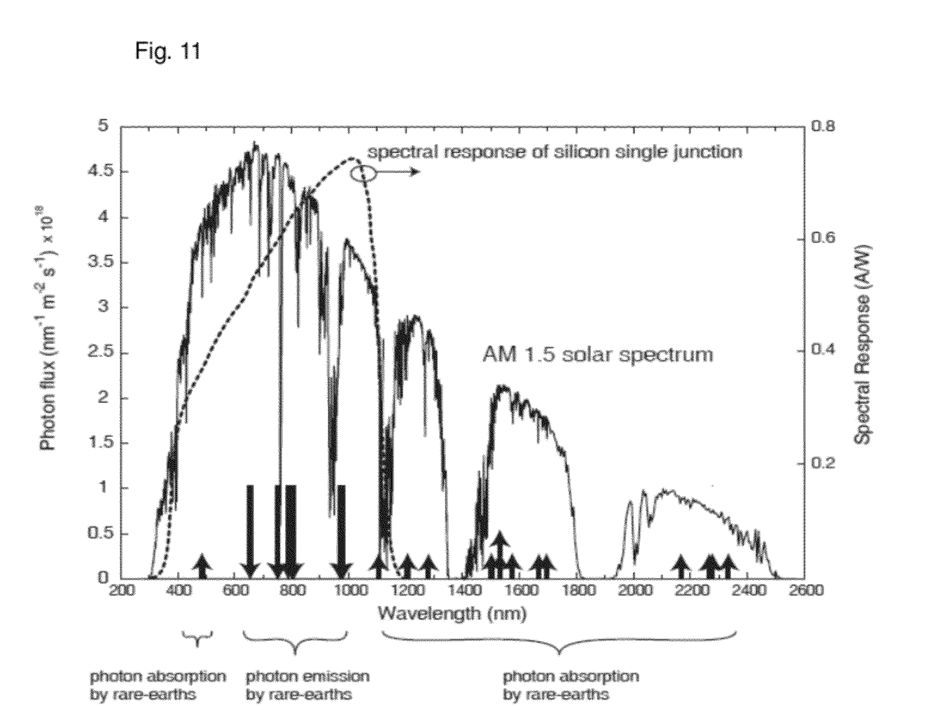

In general the Group IV layer, nanocrystal, quantum dot or inclusion absorbs a photon and generates an exciton; the exciton may be bound to a Group IV site; alternatively an exciton may recombine radiatively, emitting a photon with energy based on the Group IV site size, such the nanocrystal or quantum dot size. With rare earth present an exciton can recombine non-radiatively by bringing a rare earth ion into one of its excited states. Alternatively, other energy transfer processes may be operable; energy transfer from a Group IV material to a rare earth material may be based on phonon transfer, resonant energy transfer and/or emission of a localized, non-radiative photon. The instant invention discloses the use Group IV materials as broad band absorbers and narrow band emitters coupled to localized, narrow band, rare earth absorbers operable as emitters at predetermined frequencies. A detailed explanation of energy transfer processes is found in Chapter Five of “Novel Solar Cell Concepts” by J. C. Goldschmidt, Ph.D. Dissertation, September 2009; incorporated herein in its entirety by reference. FIG. 11 shows various absorption wavelengths for various REO[N] combinations with associated emission energies after up-conversion.

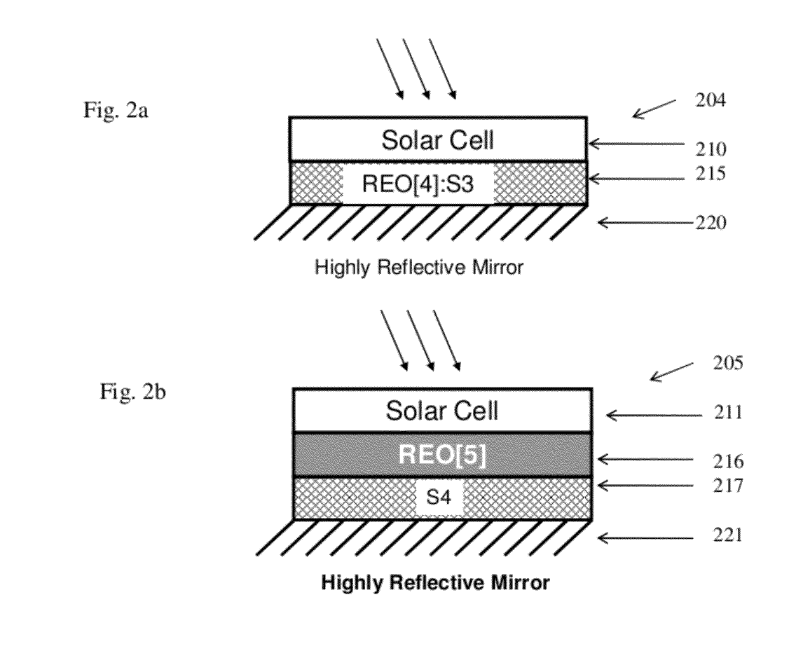

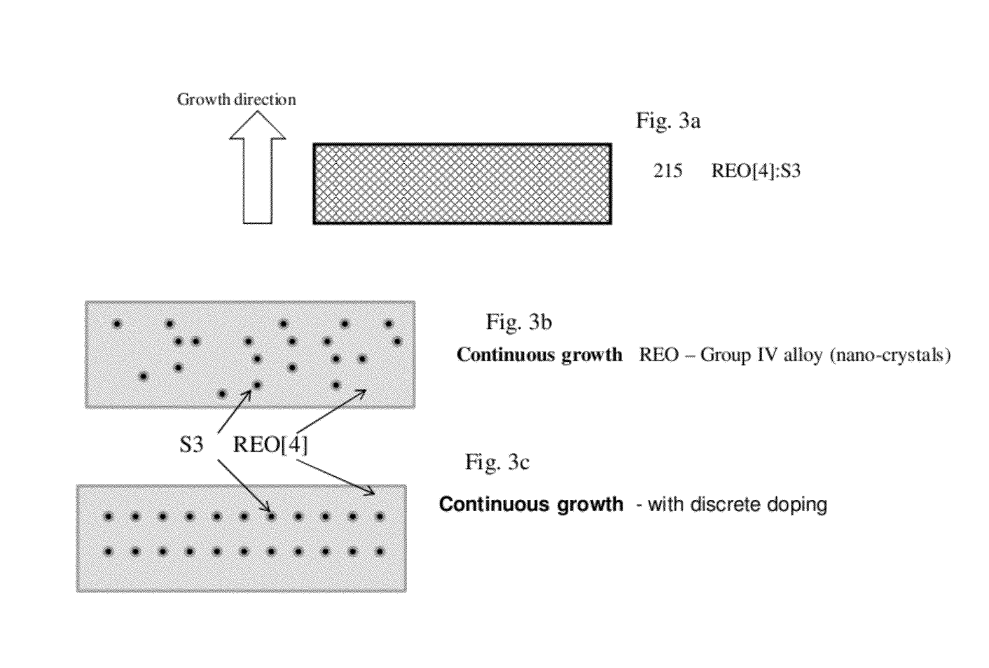

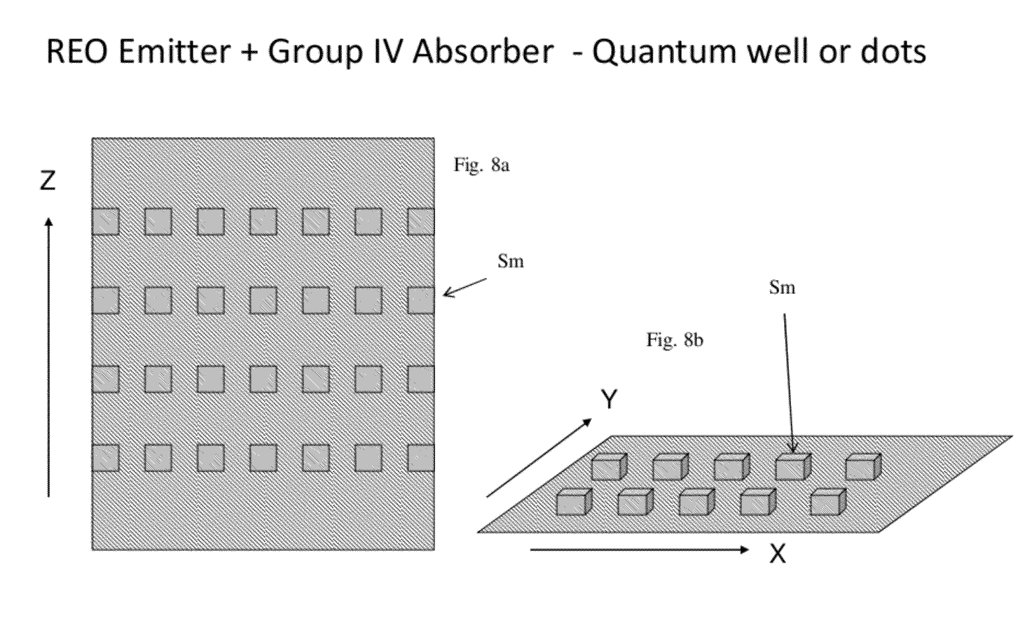

FIG. 2a is an alternative embodiment; structure 204 comprises REO[4] layer 215 comprising a Group IV mixture, S3, located between solar cell 210 and reflective layer 220. FIG. 2b is an alternative embodiment; structure 205 comprises REO[5] layer 216 and layer 217 comprising Group IV composition S4, located between solar cell 211 and reflective layer 221. Solar cells 210 and 211 may be a single cell or multiple cells; layers 215 and 216/217 are designed to absorb in a spectral range not absorbed by the solar cell and re-emit radiation in a range capable of absorption by the solar cell, thus increasing its efficiency. The term “spectral harvesting” is used to define the process of wavelength shifting by an REO layer, such as 215 and 216, optionally with Group IV additives or sensitizers, as in layer 215; broadband absorption by a layer such as 217 is also occurring with subsequent energy transfer to rare earth layer REO[4], 216. In all cases the compositions REO[4, 5], S3 and S4 are selected based upon the overall device, 204 or 205, construction; optionally one or more layers of device 204 or 205 is in a state of strain to enhance its functionality. FIG. 3a is REO[4]:S3 layer 215, showing the growth direction in a vertical fashion wherein a REO emitter is combined with a Group IV absorber, S3, in a single layer; FIG. 3b shows an example of S3 nano-crystals being randomly distributed throughout the layer; FIG. 3c shows S3 nano-crystals being distributed in a discrete manner, also termed “delta doping”. In this embodiment S3 is, optionally, a quantum dot or nano-crystal in a REO matrix; quantum dot compositions are quantized in both the z (growth) direction and in the x, y plane, as shown in FIG. 8.

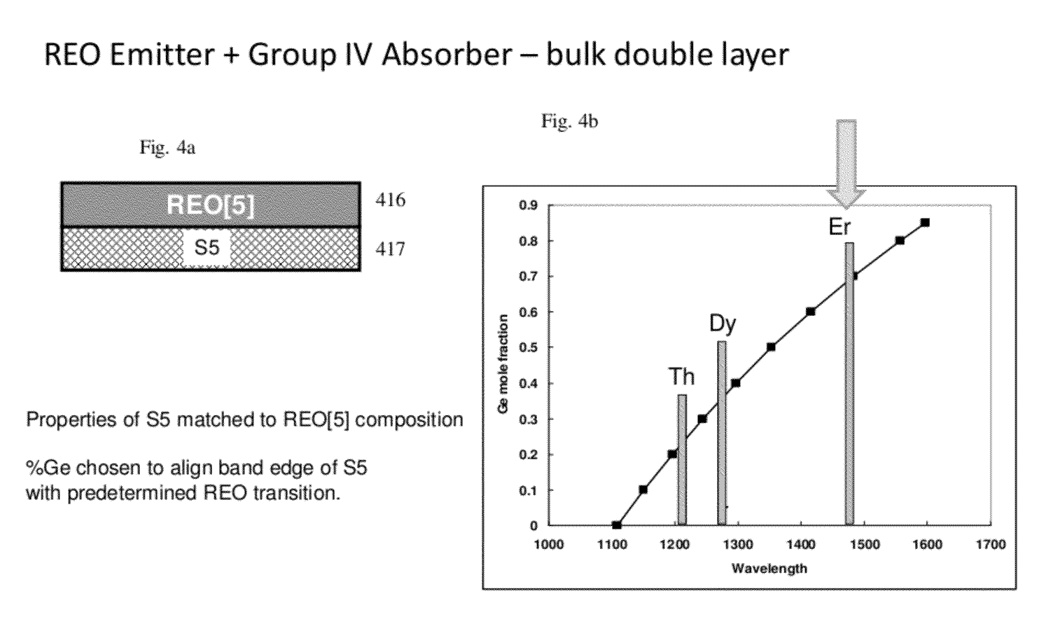

FIG. 4a illustrates an REO[5] 416 emitter and Group IV 417 absorber as a bulk double layer, as 416 and 417. In this case the properties and composition of S5 is matched to a desired transition; such as, up conversion by Er absorbing at 1,480 nm and exhibiting photoluminescence at 980 nm. A Group IV absorber is tuned with a Ge mole fraction of about 0.7 to transfer energy at 1480 nm to an Er based rare earth for up conversion to 980 nm and absorption by an adjacent solar cell such as 210 or 211.

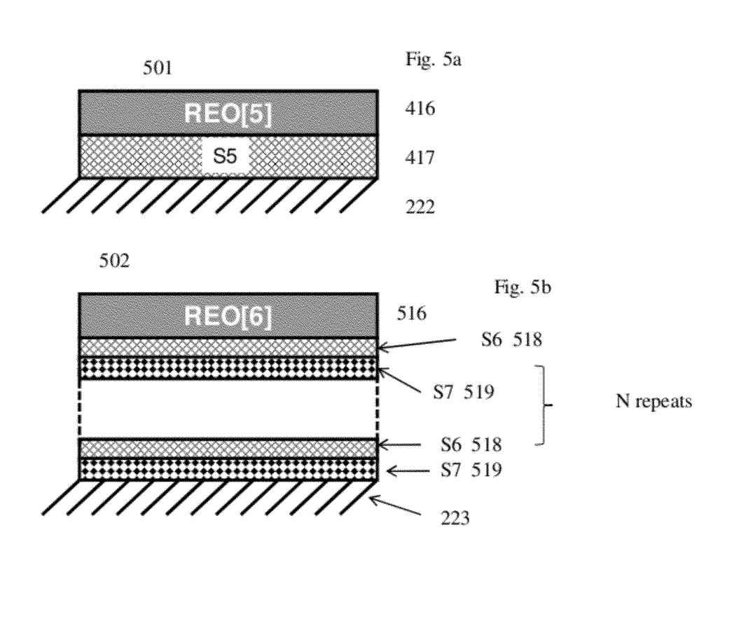

FIGS. 5a and b show alternative embodiments 501 and 502 wherein there are single, 501, or multiple layers, 502, of an REO emitter matched to a Group IV absorber Sm, optionally, REO1/S1, REO2/S2, . . . REOn/Sm. In some embodiments compositions REOn 516 and Sm are chosen to impart a strain in the Group IV layer and/or REO layer. Alternatively, S6, 518, and S7, 519, may repeat one or more times for N pairs; optionally reflective layers 222 and 223 are mirrors or Distributed Bragg Reflectors or other means for reflecting radiation back through structures 501 and 502. In this manner strain between S5, 417, and REO[5] of layer 416 can be constructed from S6, 518, and S7, 519; for example S6 may be Si_{0.4}Ge_{0.6} and S7 may be Si_{0.6}Ge_{0.4}. By using multiple layers of predetermined composition the lattice parameter of a given layer is decoupled from a given band gap constraint. In this way a rare-earth, REO/Group IV spectral conversion structure is fabricated on, underneath, or within solar cell device structures for the purpose of modifying the spectral distribution of the incident radiation and harvesting radiation previously not converted.

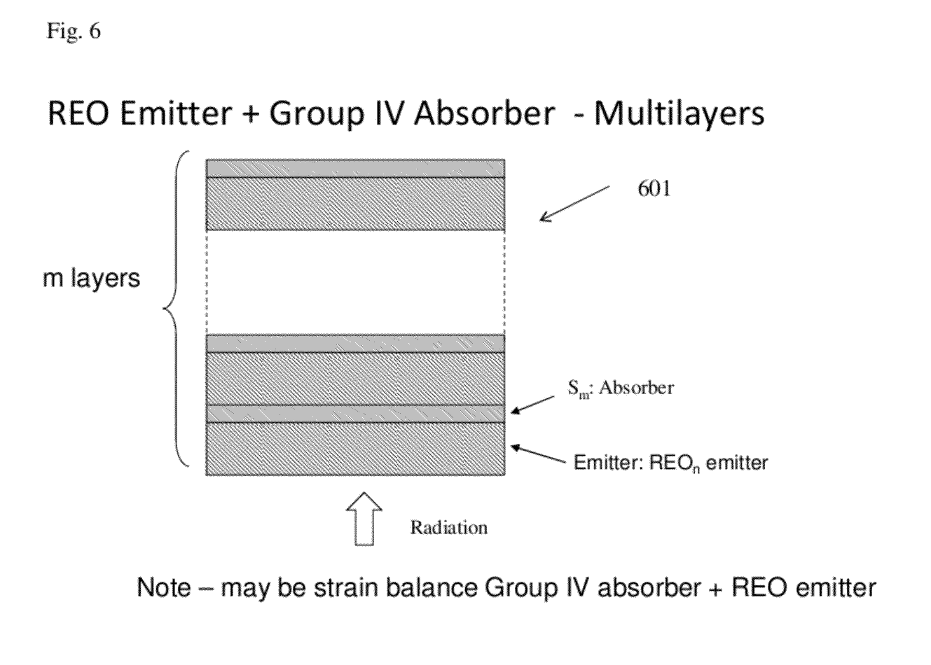

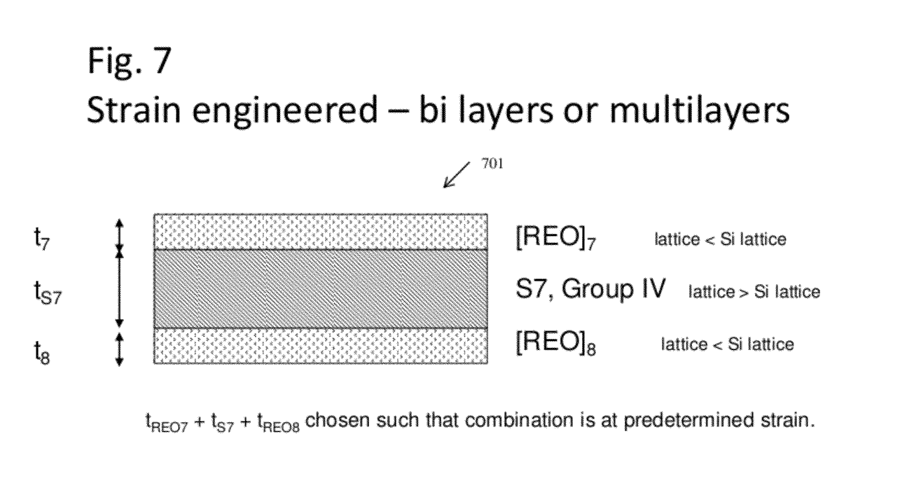

FIG. 6 illustrates an embodiment 601 wherein the Group IV layer, Sm, and REOn layers repeat at least once to m pairs. FIG. 7 illustrates an example of strain engineering wherein a Group IV layer, S7, is between [REO]₇ and [REO]₈ layers, of thickness t₇ and t₈. The structure 701 is designed such that the strain in each layer is predetermined to optimize absorption and energy transfer by the S7 layer. In some embodiments there are multiple layers of Sm and [REO]n, as noted in FIGS. 5 and 6. FIGS. 8a and b illustrate embodiments wherein a Group IV material, Sm, is, optionally, a quantum dot or nano-crystal or inclusion in a REO matrix; quantum dot compositions are quantized in both the z (growth), FIG. 8a, direction and in the x, y plane, FIG. 8b.

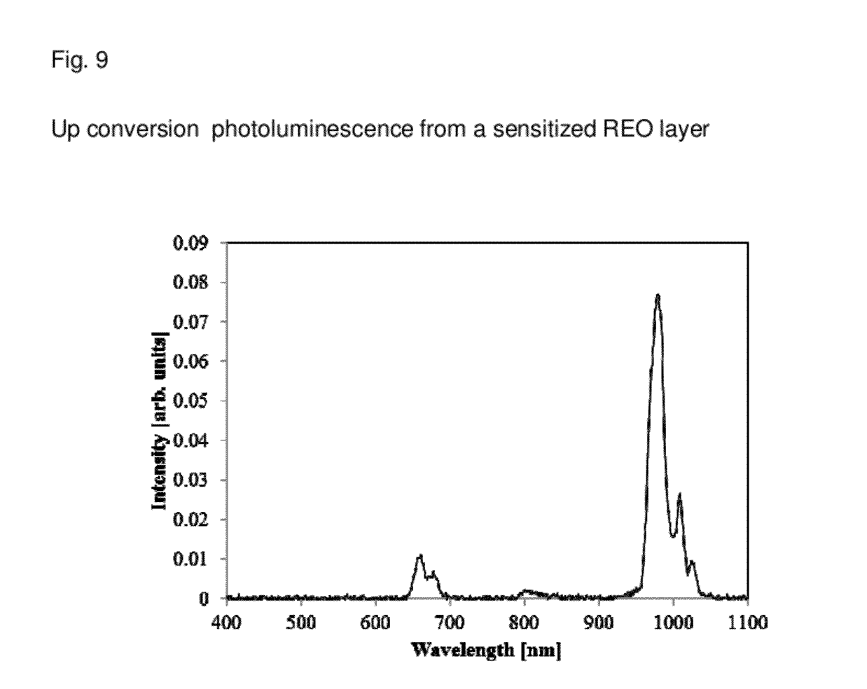

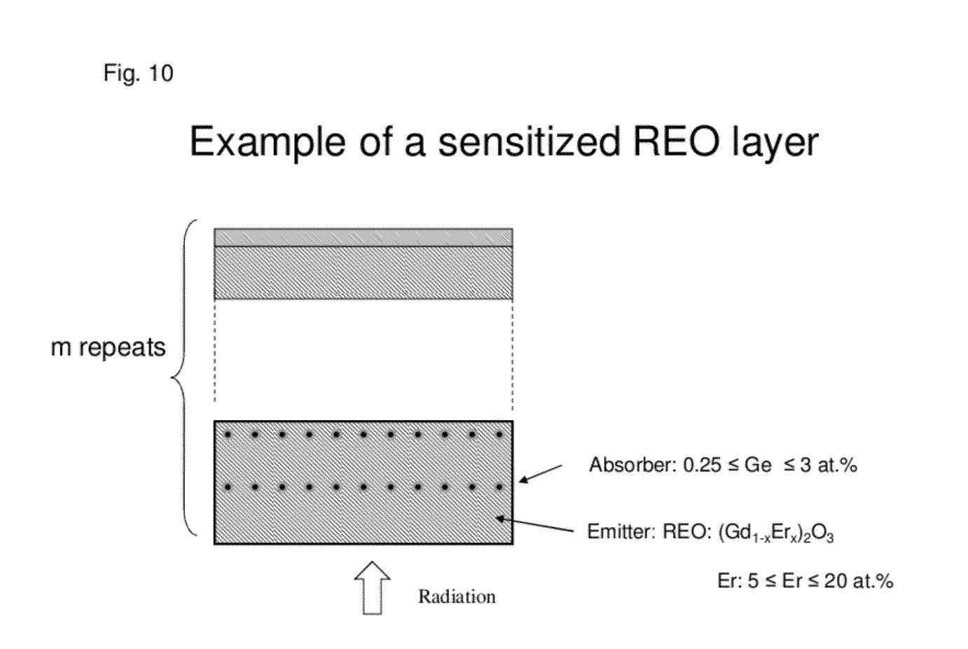

FIG. 9 shows up-conversion photoluminescence data from a REO layer comprising Group IV sensitizers with REO up-conversion emission about 650 nm and 980 nm. FIG. 10 is an exemplary REO layer with germanium sensitizer wherein 0.25≦Ge≦3 at. % and the REO matrix is (Gd₁₋ₓErₓ)₂O₃ with Er between about 5 and 20 at. %.; optionally, layers may repeat in a fashion as described in FIGS. 5, 6 and 7.

A growth or deposition process may be any one, or combination, of those known to one knowledgeable in the art; exemplary processes include CVD, MOCVD, PECVD, MBE, ALE, PVD, electron beam evaporation, multiple source PVD. In some embodiments a rare-earth layer(s) functions as a transition region between similar or dissimilar semiconducting layers and also functions as an up and/or down converting region for converting a portion of incident radiation to higher or lower energy. An exemplary structure may be a multiple-junction solar cell wherein one region comprises a silicon p-n junction cell, a second region is a rare-earth transition region functioning as a defect sink and an up converter and a third region is a germanium p-n junction cell; optionally, a first or second region may be alternative Group IV, Group III-V or Group II-VI semiconductors.

In some embodiments a rare-earth layer(s) transition region may comprise sensitizers to enhance up conversion. In some embodiments a sensitizer may be a discrete layer in a transition region; alternatively a rare-earth layer(s) transition region may comprise a sensitizer as part of its overall composition; alternatively a rare-earth layer(s) transition region may comprise a sensitizer in the form of quantum dots in a rare-earth based matrix; alternatively, a sensitizer may take more than one form in a rare-earth layer(s) transition region such as quantum dots and part of an overall composition of a rare-earth matrix.

In some embodiments a rare-earth layer transition region comprises a first rare-earth portion of first composition adjacent to a first semiconductor region, a second rare-earth portion of second composition adjacent to a second semiconductor region and a third rare-earth portion of third composition separating the first and second rare-earth portion; in some embodiments the third rare earth composition varies from the first rare-earth composition to the second rare-earth composition in a linear fashion; alternatively the third rare earth composition may vary in a step-wise fashion; alternatively, the third rare earth region may comprise multiple layers, each with a distinct composition determined by a desired stress profile to facilitate the capture and/or annihilation of lattice defects as may be generated by the transition from the first and second semiconductor regions during a growth process and subsequent process steps. In some embodiments a third rare earth region may transition from a compressive stress to a tensile stress based upon the beginning and ending compositions.

Substantially single crystal multilayer structures allow for the formation of low dislocation density material with low structure defects. Electronic propagation parallel and perpendicular to the plane of the layers is therefore improved compared to polycrystalline material. Alternatively, in some embodiments, a first semiconductor layer may be polycrystalline, large grained crystalline or micro/nano crystalline; subsequent layers may also be polycrystalline, large grained crystalline or micro/nano crystalline. As used herein, large grained is defined as a grain of lateral dimension much larger than the dimension in the growth direction.

Rare earth oxide materials for spectral conversion have previously been disclosed in U.S. application Ser. No. 12/408,297; various spectral conversion layers relative to the solar cell are disclosed. To improve the conversion efficiency of these materials, and/or reduce the thickness of spectral conversion material required, a “sensitizer” component may be added to the spectral conversion material. The instant invention discloses a sensitizer component, a transition metal, TM, such as chrome or vanadium, incorporated into or distinctly adjacent to a rare-earth containing material; a sensitizer may be incorporated into a layer comprising rare earths, a distinct transition metal layer or in the form of nanodots embedded within or adjacent to the rare-earth containing layer; alternatively silicon, germanium, tin or other Group IV elements or mixtures thereof with dimensions less than about 100 nm within a rare earth based matrix may function as a sensitizer. The function of the sensitization material is to absorb radiation for spectral conversion. In the case of an up converter photovoltaic device, long wavelength radiation beyond the spectral range of the ‘host’ device is absorbed by the sensitizer material. Through a resonant energy transfer process, the absorbed energy is transferred to the rare-earth ions contained in the up conversion material, or in an adjacent layer of up conversion material. The purpose of using a sensitizer component in the up conversion material is to widen the spectral absorption band of the up converter and also increase the absorbance. The effect of this is to absorb a greater amount of radiation in a thinner device.

Sensitized spectral conversion layers for photovoltaic devices are disclosed in this invention, including types represented by the formula [RE1]ₐ[RE2]_{b}[RE3]_{c}[TM1]_{d}[TM2]ₑ[TM3]_{f}[O]_{g}[P]ₕ[N]ᵢ, where 0<a, d, at least one of g, h, i≧0, and 0≦b, c, e, f; optionally, at least two of g, h, i≧0, with RE1,2,3 and TM1, 2, 3 chosen from the groups defined previously; 0, N, P are the symbols for oxygen, nitrogen, phosphorus. Alternatively, in some embodiments, sensitized spectral conversion layers for photovoltaic devices are disclosed with formulas being [RE1]ₐ[RE2]_{b}[RE3]_{c}[TM1]_{d}[TM2]ₑ[TM3]_{f}[O]_{g}[P]ₕ[N]ᵢ:[SiⱼGeₖ], where: [IVⱼIVₖ] represents a distinct layer of a Group IV material or a mixture of at least two; alternatively, in some embodiments Group IV materials, optionally, Si and/or Ge, are present as nanocrystals with dimensions less than about 100 nm within a [RE1]ₐ[RE2]_{b}[RE3]_{c}[TM1]_{d}[TM2]ₑ[TM3]_{f}[O]_{g}[P]ₕ[N]ᵢ, matrix wherein an overall composition of [RE1]ₐ[RE2]_{b}[RE3]_{c}[TM1]_{d}[TM2]ₑ[TM3]_{f}[O]_{g}[P]ₕ[N]ᵢ:[IVⱼIVₖ], is described by [0<a, (one of g, h, i) and at least one of (j or k)≧0], and [0≦b, c, d, e, f, (two of g, h, i) and one of (j or k)≧0]; optionally [IVⱼIVₖ] may be C, Si, Ge, Sn and/or mixtures thereof.

In some embodiments a solid state device for converting incident radiation into electrical energy comprises a structure comprising; a first region of first rare earth composition [REO]n; a second region of second composition, Sm, consisting of Group IV elements in contact with the first region wherein the first region is in a first state of strain and the second region is in a second state of strain such that the second region is operable as a direct band gap semiconductor; optionally, the device composition of the second region is operable to absorb a portion of the incident radiation and transfer a portion of the absorbed incident radiation to the first region; optionally, the device has a second region of a composition described by CᵥSiₓGe_{y}Sn_{z}, S₁, and at least one of (v, x, y, z) is greater than zero; optionally, the device has a second region comprising a first layer and a second layer wherein the first layer is a first composition described by CᵥSiₓGe_{y}Sn_{z} and the second layer is a second composition described by CₐSi_{b}Ge_{c}Sn_{d}, S₂, and at least one of (v, x, y, z) and at least one of (a, b, c, d) is greater than zero; optionally, the device composition of the first region is described by [RE1]ᵥ[RE2]_{w}[RE3]ₓ[J1]_{y}[J2]_{z}, [REO]p, wherein [RE] is chosen from a rare earth; [J1] and [J2] are chosen from a group consisting of Oxygen (O), Nitrogen (N), and Phosphorus (P), and 0≦v, w, z≦5, and 0<x, y≦5; optionally, the device has a second region operable to convert a portion of the incident radiation from a first energy to a second energy.

In some embodiments a solid state device for converting incident radiation into electrical energy comprises a first region comprising rare earth ions of first composition and quantum dots of second composition described by CᵥSiₓGe_{y}Sn_{z} wherein at least one of (v, x, y, z) is greater than zero such that the quantum dots are operable to convert a portion of the incident radiation from a first energy to a second energy and transfer the second energy to the rare earth ions; optionally, the device first region is operable to photoluminesce at a predetermined wavelength as determined by the first composition.

In some embodiments a solid state device for converting incident radiation into electrical energy comprises a photovoltaic cell, a first region comprising rare earth ions of composition [REO]₁ adjacent the photovoltaic cell; and a second region comprising a Group IV semiconductor in contact with the first region wherein the Group IV semiconductor is operable to convert a portion of the incident radiation from a first energy to a second energy and place a portion of the rare earth ions in an excited state by transfer of the second energy to the rare earth ions such that the excited rare earth ions are operable to photoluminesce at predetermined wavelengths; optionally, the device first region has a composition described by (Gd₁₋ₓErₓ)₂O₃ with Er between about 5 and 20 atom percent; optionally, the device second region has a composition described by CᵥSiₓGe_{y}Sn_{z} wherein at least one of (v, x, y, z) is greater than zero; optionally, the device second region has a composition described by Ge_{1-x-y}SiₓSn_{y} wherein the band gap is between about 0.70 eV and about 1.50 eV; optionally, the device second region is a plurality of quantum dots or nano-crystals distributed in a predetermined fashion within the first region; optionally, the device second region is a layer of Group IV semiconductor material, Sm, in contact with the first region; optionally, the device first region comprises a first portion of first composition, [REO]₁, and first thickness adjacent the photovoltaic cell and a second portion of second composition, [REO]₂, and second thickness separated from the first portion by the second region wherein the first portion and the second portion exert a strain on the second region such that the second region is operable to convert a portion of the incident radiation from a first energy to a second energy.

The foregoing described embodiments of the invention are provided as illustrations and descriptions. They are not intended to limit the invention to a precise form as described. In particular, it is contemplated that functional implementation of invention described herein may be implemented equivalently in various combinations or other functional components or building blocks. Other variations and embodiments are possible in light of above teachings to one knowledgeable in the art of semiconductors, thin film deposition techniques, and materials; it is thus intended that the scope of invention not be limited by this Detailed Description, but rather by Claims following. All patents, patent applications, and other documents referenced herein are incorporated by reference in their entirety for all purposes, unless otherwise indicated.

We claim:

1. A solid state device for converting incident radiation into electrical energy comprising a structure comprising;
a first region of first rare earth composition;
a second region of second composition consisting of Group IV elements in contact with the first region wherein the first region is in a first state of strain and the second region is in a second state of strain such that the second region is operable as a direct band gap semiconductor.

2. The device of claim 1 wherein the composition of the second region is operable to absorb a portion of the incident radiation and transfer a portion of the absorbed incident radiation to the first region.

3. The device of claim 2 wherein the second region is of a composition described by CᵥSiₓGe_{y}Sn_{z} and at least one of (v, x, y, z) is greater than zero.

4. The device of claim 2 wherein the second region comprises a first layer and a second layer wherein the first layer is a first composition described by CᵥSiₓGe_{y}Sn_{z} and the second layer is a second composition described by CₐSi_{b}Ge_{c}Sn_{d} and at least one of (v, x, y, z) and at least one of (a, b, c, d) are greater than zero.

5. The device of claim 1 wherein the composition of the first region is described by [RE1]ᵥ[RE2]_{w}[RE3]ₓ[J1]_{y}[J2]_{z} wherein [RE] is chosen from a rare earth; [J1] and [J2] are chosen from a group consisting of Oxygen (O), Nitrogen (N), and Phosphorus (P), and 0≦v, w, z≦5, and 0<x, y≦5.

6. The device of claim 1 wherein the second region is operable to convert a portion of the incident radiation from a first energy to a second energy.

7. A solid state device for converting incident radiation into electrical energy comprising;
a first region comprising rare earth ions of first composition and quantum dots of second composition described by CᵥSiₓGe_{y}Sn_{z} wherein at least one of (v, x, y, z) is greater than zero such that the quantum dots are operable to convert a portion of the incident radiation from a first energy to a second energy and transfer the second energy to the rare earth ions.

8. The device of claim 7 wherein the first region is operable to photoluminesce at a predetermined wavelength as determined by the first composition.

9. A solid state device for converting incident radiation into electrical energy comprising;
a photovoltaic cell;
a first region comprising rare earth ions of composition [REO]₁ adjacent the photovoltaic cell; and
a second region comprising a Group IV semiconductor in contact with the first region wherein the Group IV semiconductor is operable to convert a portion of the incident radiation from a first energy to a second energy and place a portion of the rare earth ions in an excited state by transfer of the second energy to the rare earth ions such that the excited rare earth ions are operable to photoluminesce at a predetermined wavelength.

10. The device of claim 9 wherein the first region has a composition described by (Gd₁₋ₓErₓ)₂O₃ with Er between about 5 and 20 atom percent.

11. The device of claim 9 wherein the second region has a composition described by CᵥSiₓGe_{y}Sn_{z} wherein at least one of (v, x, y, z) is greater than zero.

12. The device of claim 9 wherein the second region has a composition described by Ge_{1-x-y}SiₓSn_{y} wherein the band gap is between about 0.70 eV and about 1.50 eV.

13. The device of claim 9 wherein the second region is a plurality of quantum dots or nano-crystals distributed in a predetermined fashion within the first region.

14. The device of claim 9 wherein the second region is a layer of Group IV semiconductor material, Sm, in contact with the first region.

15. The device of claim 9 wherein the first region comprises a first portion of first composition, [REO]₁, and first thickness adjacent the photovoltaic cell and a second portion of second composition, [REO]₂, and second thickness, separated from the first portion by the second region wherein the first portion and the second portion exert a strain on the second region such that the second region is operable to convert a portion of the incident radiation from a first energy to a second energy.
